(19) United States
(12) Patent Application Publication
(10) Pub. No.: US 2026/0112403 A1
(43) Pub. Date: Apr. 23, 2026

(54) Extended Length Memory System with Multiple Channels

(71) Applicant: Advanced Micro Devices, Inc., Santa Clara, CA (US)

(72) Inventors: Aaron John Nygren, Boise, ID (US); Bhyrav M Mutnury, Round Rock, TX (US); Ravi B Bingi, Austin, TX (US); Christopher Edward Cox, Placerville (CA)

(73) Assignee: Advanced Micro Devices, Inc., Santa Clara, CA (US)

(21) Appl. No.: 19/253,582

(22) Filed: Jun. 27, 2025

Related U.S. Application Data
(60) Provisional application No. 63/709,913, filed on Oct. 21, 2024.

(51) Int. Cl. G11C 11/408; G11C 5/04; G11C 5/06; G11C 5/14

(52) U.S. Cl. CPC G11C 11/4082; G11C 5/04; G11C 5/06; G11C 5/147

(57) ABSTRACT

An extended length memory module with multiple channels is described. In one or more implementations, a memory module comprises a printed circuit board having a first length that is greater than a second length of memory modules. The memory module includes multiple memory chips mounted on the printed circuit board. Multiple buffers are also mounted on the printed circuit board, and those buffers are configured to handle memory operations across at least three channels for accessing the memory chips. The greater length of the printed circuit board allows for increased memory capacity and bandwidth within a single module form factor while maintaining compatibility with existing memory architectures.

### RELATED APPLICATION

This application claims priority to U.S. Provisional Application Ser. No. 63/709,913, filed 21 Oct. 2024, titled “Extended Length Memory Module with Multiple Channels,” the disclosure of which is incorporated by reference herein in its entirety.

### BACKGROUND

Dual In-Line Memory Modules (DIMMs) are circuit boards that hold dynamic random-access memory (DRAM) chips, which serve as the memory for many computers. Over time, advancements in DIMM technology (e.g., DDR4 to DDR5)—such as increases in speed, higher data transfer rates, and larger storage capacities—have improved computer performance, enabling faster data processing, smoother multitasking, and support for memory-intensive applications like virtual machines, large-scale databases, and artificial intelligence workloads. These innovations can also contribute to energy efficiency, which reduces power consumption while delivering higher performance.

### BRIEF DESCRIPTION OF THE DRAWINGS

FIG. 1 is a block diagram of a processing system configured to execute one or more applications, in accordance with one or more implementations.

FIG. 2 is a block diagram of a non-limiting example of a memory system.

FIG. 3 is a block diagram of a non-limiting example of pins of multiple memory die of a memory chip, such as of a stacked DRAM.

FIG. 4 is a block diagram of a non-limiting example of a first memory module having a conventional length and a second memory module having a length that is greater than the conventional length.

FIG. 5 is a block diagram of a non-limiting example of a memory module having a length that is greater than the conventional length and having a different buffer configuration for handling memory channels than the preceding example.

FIG. 6 is a block diagram of a non-limiting example of a memory module having a length that is shorter than a conventional length.

FIG. 7 depicts a procedure in an example implementation of an extended length memory system with multiple channels.

FIG. 8 depicts a procedure in an example implementation of an extended length memory system with multiple channels using a different buffer configuration from the preceding example.

### DETAILED DESCRIPTION

Conventional memory modules of today are often limited to two memory channels and a fixed number of memory chips (e.g., DRAM) due to physical size constraints. This restricts the maximum memory capacity and bandwidth that can be achieved within a single module and within a distance of a host such as a system on chip (SoC). Additionally, increasing memory density by adding more layers to the printed circuit board (e.g., further away from the host or SoC) can lead to signal integrity issues and increased manufacturing costs, particularly for those memory modules further away from the host or SoC.

A memory system having a first length that is greater than a second length of memory systems and having multiple channels is described. One example of the second length is a length of today's memory modules which meet a standard, such as JEDEC's standard for DDR5 or earlier double data rate configurations of memory modules. In accordance with the described techniques, a “memory module,” such as an in-line memory module, is an example of a memory system. One example type of in-line memory module is a Dual In-Line Memory Module or “DIMM. ” Memory systems as described herein, which have an extended length relative to conventional lengths of memory systems, provide increased memory capacity and bandwidth while maintaining compatibility with existing memory architectures. By lengthening the printed circuit board of a memory system to approximately 1.5 times a conventional length, for instance, such a system can accommodate additional memory chips and support more memory channels compared to conventional memory modules, while also being physically compatible for easy integration into many existing systems. With many conventional system architectures, a memory module having approximately twice a conventional length would be too large to integrate easily within such systems while a memory module having only about 1.5 times the conventional length would fit suitably within the architecture.

In contrast to conventional 133.35-millimeter to 135-millimeter DIMMs, extended length memory systems as described herein overcome the limitations of conventional memory modules by providing space for additional memory chips, e.g., at least one additional cluster of memory chips. This allows for implementation of a third memory channel, for example, potentially resulting in a 50% increase in both memory capacity and bandwidth compared to conventional memory modules. Although the memory systems described herein have a length that is greater than conventional lengths, in variations, those memory systems maintain approximately a same height and thickness as conventional memory modules, e.g., DIMMs configured according to a JEDEC standard for DDR5 or an earlier double data rate configuration.

To handle the additional memory channel, extended length memory systems incorporate multiple buffer chips. These buffers can be configured in various ways, such as using three separate buffers (one for each channel) or two buffers with one buffer handling two channels and the other handling the third channel. This flexibility in buffer configuration allows for optimized signal routing and improved performance.

In some aspects, the techniques described herein relate to a memory system, including: a printed circuit board having a first length greater than a second length of memory systems, a plurality of memory chips mounted on the printed circuit board, and a plurality of buffers mounted on the printed circuit board, wherein the plurality of buffers are configured to handle memory access requests across at least three channels for accessing the plurality of memory chips.

In some aspects, the techniques described herein relate to a memory system, wherein the second length is between a range of approximately 133.35 millimeters and 135 millimeters.

In some aspects, the techniques described herein relate to a memory system, wherein the first length is between a range of approximately 200.025 millimeters and 202.5 millimeters.

In some aspects, the techniques described herein relate to a memory system, wherein the plurality of buffers includes three buffers each configured to handle the memory access requests for a respective one of the at least three channels.

In some aspects, the techniques described herein relate to a memory system, wherein the plurality of buffers includes a first buffer and a second buffer, wherein the first buffer is configured to handle the memory access requests for two of the at least three channels and the second buffer is configured to handle the memory access requests for a third channel.

In some aspects, the techniques described herein relate to a memory system, wherein the plurality of memory chips includes dynamic random-access memory (DRAM) chips, and wherein at least one of the DRAM chips is a stacked DRAM including multiple memory die.

In some aspects, the techniques described herein relate to a memory system, further including a memory controller integral with the printed circuit board.

In some aspects, the techniques described herein relate to a memory system, wherein the memory system has a first pin count of connector pins that is greater than a second pin count of memory systems.

In some aspects, the techniques described herein relate to a memory system, further including a plurality of voltage regulators distributed across the first length of the printed circuit board to output a substantially fixed voltage to at least one of the plurality of memory chips or the plurality of buffers.

In some aspects, the techniques described herein relate to a method including: receiving, at a first buffer of a plurality of buffers of a memory system, a first memory access request for a plurality of memory chips of the memory system, wherein the plurality of buffers and the plurality of memory chips are integral with a printed circuit board of the memory system having a first length greater than a second length of memory systems, routing, by the first buffer, the received first memory access request over a first channel to access a first portion of memory implemented by the plurality of memory chips, receiving, at a second buffer of the plurality of buffers, a second memory access request for the plurality of memory chips of the memory system, routing, by the second buffer, the received second memory access request over a second channel to access a second portion of the memory implemented by the plurality of memory chips, receiving, at a third buffer of the plurality of buffers, a third memory access request for the plurality of memory chips of the memory system, and routing, by the third buffer, the received third memory access request over a third channel to access a third portion of the memory implemented by the plurality of memory chips.

In some aspects, the techniques described herein relate to a method, wherein the memory system is configured to access the memory implemented by the plurality of memory chips using only three channels.

In some aspects, the techniques described herein relate to a method, further including receiving the first memory access request via a first plurality of connector pins of the memory system, receiving the second memory access request via a second plurality of connector pins of the memory system, and receiving the third memory access request via a third plurality of connector pins of the memory system:

In some aspects, the techniques described herein relate to a method, wherein the first plurality of connector pins, the second plurality of connector pins, and the third plurality of connector pins total a first pin count that is greater than a second pin count of memory systems.

In some aspects, the techniques described herein relate to a method, wherein the first memory access request, the second memory access request, and the third memory access request are received from a host to which the memory system is connected via connector pins of the memory system.

In some aspects, the techniques described herein relate to a method, wherein the host is a system on chip.

In some aspects, the techniques described herein relate to a method, wherein at least one memory chip of the plurality of memory chips is a stacked dynamic random-access memory (DRAM) with multiple memory die.

In some aspects, the techniques described herein relate to a computing system, including: a processor, a memory controller communicatively coupled to the processor, and a memory system communicatively coupled to the memory controller, the memory system including: a printed circuit board having a first length greater than a second length of memory systems, a plurality of memory chips mounted on the printed circuit board, and a plurality of buffers mounted on the printed circuit board, wherein the plurality of buffers are configured to handle memory access requests across at least three channels for accessing the plurality of memory chips, and wherein the memory controller is configured to communicate with the memory system via the at least three channels.

In some aspects, the techniques described herein relate to a computing system, wherein the processor is a central processing unit or an accelerated unit.

In some aspects, the techniques described herein relate to a computing system, wherein the memory controller is included in the memory system.

In some aspects, the techniques described herein relate to a computing system, wherein the processor is configured to execute instructions to perform operations on data accessed from the plurality of memory chips via the at least three channels.

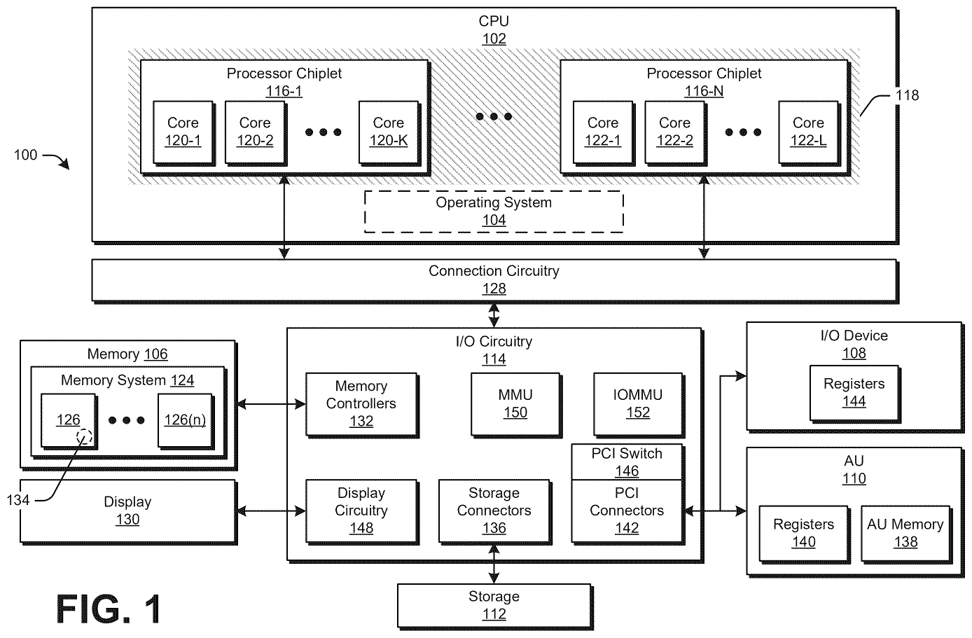

FIG. 1 is a block diagram of a processing system configured to execute one or more applications, in accordance with one or more implementations.

FIG. 1 includes a processing system 100 configured to execute one or more applications, such as compute applications (e.g., machine-learning applications, neural network applications, high-performance computing applications, databasing applications, gaming applications), graphics applications, and the like. Examples of devices in which the processing system is implemented include, but are not limited to, a server computer, a personal computer (e.g., a desktop or tower computer), a smartphone or other wireless phone, a tablet or phablet computer, a notebook computer, a laptop computer, a wearable device (e.g., a smartwatch, an augmented reality headset or device, a virtual reality headset or device), an entertainment device (e.g., a gaming console, a portable gaming device, a streaming media player, a digital video recorder, a music or other audio playback device, a television, a set-top box), an Internet of Things (IoT) device, an automotive computer or computer for another type of vehicle, a networking device, a medical device or system, and other computing devices or systems.

In the illustrated example, the processing system 100 includes a central processing unit (CPU) 102. In one or more implementations, the CPU 102 is configured to run an operating system (OS) 104 that manages the execution of applications. For example, the OS 104 is configured to schedule the execution of tasks (e.g., instructions) for applications, allocate portions of resources (e.g., system memory 106, CPU 102, input/output (I/O) device 108, accelerator unit (AU) 110, storage 112, I/O circuitry 114) for the execution of tasks for the applications, provide an interface to I/O devices (e.g., I/O device 108) for the applications, or any combination thereof.

The CPU 102 includes one or more processor chiplets 116, which are communicatively coupled together by a data fabric 118 in one or more implementations. Each of the processor chiplets 116, for example, includes one or more processor cores 120, 122 configured to concurrently execute one or more series of instructions, also referred to herein as “threads,” for an application. Further, the data fabric 118 communicatively couples each processor chiplet 116-N of the CPU 102 such that each processor core (e.g., processor cores 120) of a first processor chiplet (e.g., 116-1) is communicatively coupled to each processor core (e.g., processor cores 122) of one or more other processor chiplets 116. Though the example embodiment presented in FIG. 1 shows a first processor chiplet (116-1) having three processor cores (120-1, 120-2, 120-K) representing a K number of processor cores 122 and a second processor chiplet (116-N) having three processor cores (e.g., 122-1, 122-2, 122-L) representing an L number of processor cores 122, in other implementations (L being an integer number greater than or equal to one), each processor chiplet 116 may have any number of processor cores 120, 122. For example, each processor chiplet 116 can have the same number of processor cores 120, 122 as one or more other processor chiplets 116, a different number of processor cores 120, 122 as one or more other processor chiplets 116, or both.

Examples of connections which are usable to implement data fabric include but are not limited to, buses (e.g., a data bus, a system, an address bus), interconnects, memory channels, through silicon vias, traces, and planes. Other example connections include optical connections, fiber optic connections, and/or connections or links based on quantum entanglement.

In this example, the memory 106 is depicted with memory system 124, which is depicted with memory chips 126. In one or more implementations, the memory system 124 corresponds to a type of memory configured according to a standard, such as according to a JEDEC standard. Additionally or alternatively, the memory system 124 is a memory module, such as an in-line memory module, an example of which is a dual in-line memory module (DIMM). In at least one example, for instance, the memory system 124 is a DIMM configured according to a JEDEC standard applicable to DIMMs, such as according to a double data rate #(DDR #) standard, where the ‘#’ symbol corresponds to an integer. In one or more implementations, the memory chips 126 are dynamic random-access memory (DRAM) chips, which are coupled to a printed circuit board forming the memory system 124. The memory system 124 is depicted with memory chip 126 and memory chip 126(n), where n represents any integer greater than or equal to 1. This represents that the memory system 124 is equipped with multiple memory chips 126 and may include various numbers of the memory chips 126. Although only one memory system 124 is depicted, in one or more implementations, the system 100 may include multiple memory systems 124, such as multiple memory systems 124 arranged in a stacked configuration. Additionally, or alternatively, multiple memory systems 124 arranged in a stack may also be arranged in a stack with one or more compute units, such as with one or more CPUs and/or portions of a CPU, e.g., cores.

Additionally, within the processing system 100, the CPU 102 is communicatively coupled to an I/O circuitry 114 by a connection circuitry 128. For example, each processor chiplet 116 of the CPU 102 is communicatively coupled to the I/O circuitry 114 by the connection circuitry 128. The connection circuitry 128 includes, for example, one or more data fabrics, buses, buffers, queues, and the like. The I/O circuitry 114 is configured to facilitate communications between two or more components of the processing system 100 such as between the CPU 102, system memory 106, display 130, universal serial bus (USB) devices, peripheral component interconnect (PCI) devices (e.g., I/O device 108, AU 110), storage 112, and the like.

As an example, system memory 106 includes any combination of one or more volatile memories and/or one or more non-volatile memories, examples of which include dynamic random-access memory (DRAM), static random-access memory (SRAM), non-volatile RAM, and the like. To manage access to the system memory 106, such as by the CPU 102, the I/O device 108, the AU 110, and/or any other components, the I/O circuitry 114 includes one or more memory controllers 132. These memory controllers 132, for example, include circuitry configured to manage and fulfill memory access requests issued from the CPU 102, the I/O device 108, the AU 110, or any combination thereof. Examples of such requests include read requests, write requests, fetch requests, pre-fetch requests, or any combination thereof. That is to say, these memory controllers 132 are configured to manage access to the data stored at one or more memory addresses within the system memory 106, such as by CPU 102, the I/O device 108, and/or the AU 110. Although the memory controllers 132 are depicted separate from the memory system 124 in this example, in one or more implementations, one or more such memory controllers are included as part of the memory system 124, e.g., incorporated on or in or otherwise attached to the printed circuit board to which the memory chips 126 are mounted.

When an application is to be executed by processing system 100, the OS 104 running on the CPU 102 is configured to load at least a portion of program code 134 (e.g., an executable file) associated with the application from, for example, a storage 112 into system memory 106, such as into one or more memory chips 126 of the memory system 124. This storage 112, for example, includes a non-volatile storage such as a flash memory, solid-state memory, hard disk, optical disc, or the like configured to store program code 134 for one or more applications.

To facilitate communication between the storage 112 and other components of processing system 100, the I/O circuitry 114 includes one or more storage connectors 136 (e.g., universal serial bus (USB) connectors, serial AT attachment (SATA) connectors, PCI Express (PCIe) connectors) configured to communicatively couple storage 112 to the I/O circuitry 114 such that I/O circuitry 114 is capable of routing signals to and from the storage 112 to one or more other components of the processing system 100.

In association with executing an application, in one or more scenarios, the CPU 102 is configured to issue one or more instructions (e.g., threads) to be executed for an application to the AU 110. The AU 110 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable logic devices (FPGAs)), or any combination thereof.

In at least one example, the AU 110 includes one or more compute units that concurrently execute one or more threads of an application and store data resulting from the execution of these threads in AU memory 138. This AU memory 138, for example, includes any combination of one or more volatile memories and/or non-volatile memories, examples of which include caches, video RAM (VRAM), or the like. In one or more implementations, these compute units are also configured to execute these threads based on the data stored in one or more physical registers 140 of the AU 110. Alternatively or additionally, the AU 110 includes memory like the memory system 124, e.g., one or more memory modules.

To facilitate communication between the AU 110 and one or more other components of processing system 100, the I/O circuitry 114 includes or is otherwise connected to one or more connectors, such as PCI connectors 142 (e.g., PCIe connectors) each including circuitry configured to communicatively couple the AU 110 to the I/O circuitry such that the I/O circuitry 114 is capable of routing signals to and from the AU 110 to one or more other components of the processing system 100. Further, the PCIe connectors 142 are configured to communicatively couple the I/O device 108 to the I/O circuitry 114 such that the I/O circuitry 114 is capable of routing signals to and from the I/O device 108 to one or more other components of the processing system 100.

By way of example and not limitation, the I/O device 108 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 108 is configured to execute one or more operations, tasks, instructions, or any combination thereof based on one or more physical registers 144 of the I/O device 108. In one or more implementations, such physical registers 144 are configured to maintain data (e.g., operands, instructions, values, variables) indicating one or more operations, tasks, or instructions to be performed by the I/O device 108.

To manage communication between components of the processing system 100 (e.g., AU 110, I/O device 108) that are connected to PCI connectors 142, and one or more other components of the processing system 100, the I/O circuitry 114 includes PCI switch 146. The PCI switch 146, for example, includes circuitry configured to route packets to and from the components of the processing system 100 connected to the PCI connectors 142 as well as to the other components of the processing system 100. As an example, based on address data indicated in a packet received from a first component (e.g., CPU 102), the PCI switch 146 routes the packet to a corresponding component (e.g., AU 110) connected to the PCI connectors 142.

Based on the processing system 100 executing a graphics application, for instance, the CPU 102, the AU 110, or both are configured to execute one or more instructions (e.g., draw calls) such that a scene including one or more graphics objects is rendered. After rendering such a scene, the processing system 100 stores the scene in the storage 112, displays the scene on the display 130, or both. The display 130, for example, includes a cathode-ray tube (CRT) display, liquid crystal display (LCD), light emitting diode (LED) display, organic light emitting diode (OLED) display, or any combination thereof. To enable the processing system 100 to display a scene on the display 130, the I/O circuitry 114 includes display circuitry 148. The display circuitry 148, for example, includes high-definition multimedia interface (HDMI) connectors, DisplayPort connectors, digital visual interface (DVI) connectors, USB connectors, and the like, each including circuitry configured to communicatively couple the display 130 to the I/O circuitry 114. Additionally or alternatively, the display circuitry 148 includes circuitry configured to manage the display of one or more scenes on the display 130 such as display controllers, buffers, memory, or any combination thereof.

Further, the CPU 102, the AU 110, or both are configured to concurrently run one or more virtual machines (VMs), which are each configured to execute one or more corresponding applications. To manage communications between such VMs and the underlying resources of the processing system 100, such as any one or more components of processing system 100, including the CPU 102, the I/O device 108, the AU 110, and the system memory 106, the I/O circuitry 114 includes memory management unit (MMU) 146 and input-output memory management unit (IOMMU) 148. The MMU 150 includes, for example, circuitry configured to manage memory requests, such as from the CPU 102 to the system memory 106. For example, the MMU 150 is configured to handle memory requests issued from the CPU 102 and associated with a VM running on the CPU 102. These memory requests, for example, request access to read, write, fetch, or pre-fetch data residing at one or more virtual addresses (e.g., guest virtual addresses) each indicating one or more portions (e.g., physical memory addresses) of the system memory 106. Based on receiving a memory request from the CPU 102, the MMU 150 is configured to translate the virtual address indicated in the memory request to a physical address in the system memory 106 and to fulfill the request. The IOMMU 152 includes, for example, circuitry configured to manage memory requests (memory-mapped I/O (MMIO) requests) from the CPU 102 to the I/O device 108, the AU 110, or both, and to manage memory requests (direct memory access (DMA) requests) from the I/O device 108 or the AU 110 to the system memory 106. For example, to access the registers 144 of the I/O device 108, the registers 140 of the AU 110, and/or the AU memory 138, the CPU 102 issues one or more MMIO requests. Such MMIO requests each request access to read, write, fetch, or pre-fetch data residing at one or more virtual addresses (e.g., guest virtual addresses) which each represent at least a portion of the registers 144 of the I/O device 108, the registers 140 of the AU 110, or the AU memory 138, respectively. As another example, to access the system memory 106 without using the CPU 102, the I/O device 108, the AU 110, or both are configured to issue one or more DMA requests. Such DMA requests each request access to read, write, fetch, or pre-fetch data residing at one or more virtual addresses (e.g., device virtual addresses) which each represent at least a portion of the system memory 106. Based on receiving an MMIO request or DMA request, the IOMMU 152 is configured to translate the virtual address indicated in the MMIO or DMA request to a physical address and fulfill the request.

In variations, the processing system 100 can include any combination of the components depicted and described. For example, in at least one variation, the processing system 100 does not include one or more of the components depicted and described in relation to FIG. 1. Additionally or alternatively, in at least one variation, the processing system 100 includes additional and/or different components from those depicted. The processing system 100 is configurable in a variety of ways with different combinations of components in accordance with the described techniques.

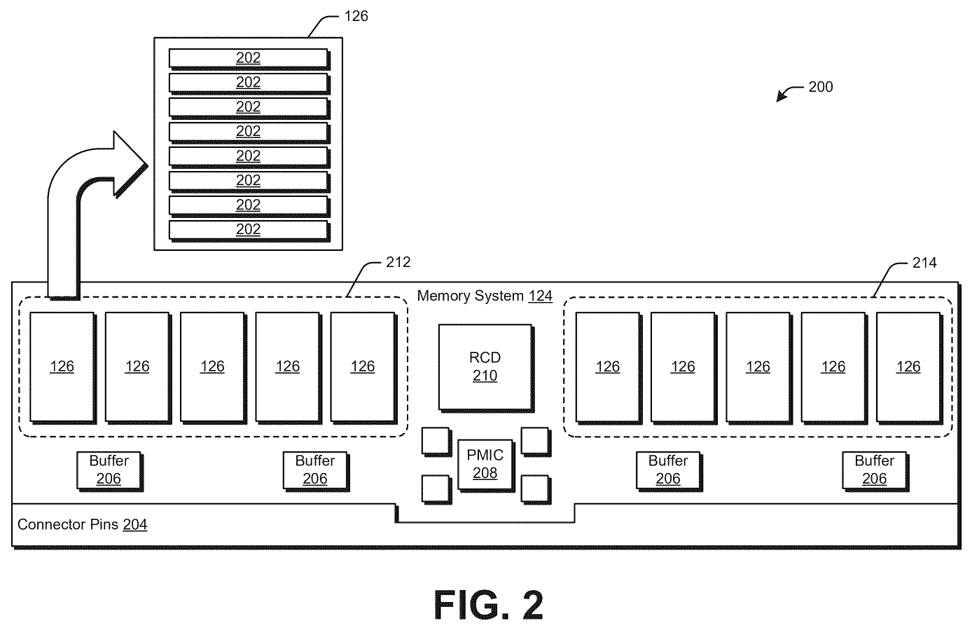

FIG. 2 is a block diagram of a non-limiting example 200 of a memory system. The illustrated example includes the memory system 124 having a plurality of the memory chips 126.

In one or more implementations, the memory system 124 is an in-line memory module, and each of the memory chips 126 is dynamic random-access memory (DRAM), such as synchronous dynamic random-access memory SDRAM. By way of example, the memory system 124 is a dual in-line memory module (DIMM). When configured as an in-line memory module, for instance, the memory system 124 includes the memory chips 126 (DRAMs) mounted communicably to a printed circuit board on one or both sides (i.e., front and/or back) of the printed circuit board. In accordance with the described techniques, the memory system 124 has a length that is greater than a conventional length of memory modules. For example, the extended length is approximately 1.5 times longer than a conventional length of memory modules, the conventional length ranging between approximately 133.35 and 135 millimeters. By way of example, the term “approximately” or “approximate” when used in connection with a range of the conventional length of memory modules, can correspond to a range between 130 millimeters and 140 millimeters. Accordingly, in one or more implementations, the extended length of the memory system 124 (e.g., of the circuit board to which the memory chips 126 are mounted) ranges from approximately seven and seven-eighths inches (7⅞ inches or 7.875 inches) 200.025 millimeters to 202.5 millimeters (7.97 inches). By way of example, the term “approximately” or “approximate” when used in connection with a range of the length of memory modules having the described novel configuration or “extended” length, can correspond to a range between 195.0 millimeters and 210.0 millimeters.

In one or more implementations, the memory system 124 is standardized, such that various aspects of the memory system 124 and/or the memory chips 126 conform to a standard, e.g., a JEDEC standard. Although ten memory chips 126 are depicted in the illustrated example, the memory system 124 can include any different integer number of memory chips 126 in accordance with the described techniques, e.g., two (2), eight (8), nine (9), twelve (12), fifteen (15), sixteen (16), twenty (20), twenty-four (24), twenty-seven (27), thirty (30), and so on.

In one or more implementations, at least one of the memory chips 126 includes a plurality of memory die 202, such as memory die arranged in a “stacked” or “3D” configuration. In connection with DRAM technology, such an arrangement may be referred to as “stacked DRAM,” “3D stacked DRAM,” or a “3D DRAM stack. ” Thus, in one or more implementations, at least one of the memory chips 126 is a stacked DRAM. This also means that each of the memory chips 126 may comprise a stack of memory die 202 in at least one variation. For example, each of the memory chips 126 is a stacked DRAM. Although the view of the memory chips 126 with the stack of memory die 202 includes eight memory die, in variations, any of the memory chips 126 may have a different integer number of memory die, e.g., four (4), five (5), ten (10), and so forth, without departing from the spirit or scope of the described techniques.

The memory system 124 also includes connector pins 204. The connector pins 204 serve as electrical connectors that are used to communicably link the memory system 124 to at least one other component of a system (e.g., of the system 100), allowing transfer over the link, for example, of data, address signals, power, control signals, command/address signals, and so on, between the memory system 124 and the rest of the system. In at least one implementation, the connector pins 204 electrically connect the memory system 124 to a motherboard or “host”. The connector pins 204 can include one or more of data transfer pins, address pins, power and ground pins, control pins, and error correcting code (ECC) pins, to name just a few. The memory system 124 may include varying integer numbers of the connector pins 204 arranged in various layouts (e.g., with double rows of pins, with offset pins, with notches or cutouts in the arrangement) and having any of a variety of shapes (e.g., rectangular, triangular, rounded rectangle, etc.), without departing from the described techniques. Additionally, the connector pins 204 may be formed of any of a variety of materials including, for example, gold and/or gold plating, which is a suitable conductor of electricity and is resistant to corrosion. In variations, one or more notches or cutouts may be present in the connector pins 204, e.g., on an outboard side of the memory system 124 resulting in a gap of space (not shown) between pins and/or on an inboard side of the memory system 124 resulting in a gap (not shown) filled with at least a portion of the printed circuit board (e.g., silicon and/or other components of a printed circuit board).

In this example, the memory system 124 is also depicted with buffer(s) 206, power management integrated circuit 208 (referred to as PMIC 208), and registered clock driver 210 (referred to as RCD 210). It is to be appreciated that in variations the memory system 124 includes different/additional components (e.g., one or more memory controllers), does not include one or more of the depicted and/or described components, includes different numbers of the depicted and/or described components (e.g., a different number of buffer(s) 206), and so on, without departing from the spirit or scope of the described techniques.

The buffer(s) 206 of the memory system 124 may include one or more types of buffers and/or buffers that perform any of a variety of functions for the memory system 124 (e.g., programmed to perform the different functions and/or configured in hardware to perform such different functions), such as data buffers, input buffers, output buffers, and so on. In one example, for instance, a buffer may be connected to two of the memory chips 126 on one side and to a system on chip (SoC) (e.g., the system 100) on the other side, enabling the memory chips 126 to communicate with the system in a time sequenced fashion. On a host side interface of the buffer to the system (e.g., an SoC), the buffer may effectively multiply a frequency up, doubling the bandwidth by having two devices (e.g., memory chips 126) on the other side of the buffer and supplying twice the data that is then serialized to the host (i.e., the system) at twice the speed.

In another example, a buffer may be programmed or otherwise configured to, in one direction of communication between the memory chips 126 (and/or one or more other components of the memory system 124) and one or more system components to which the memory system 124 is connected (e.g., a “host”), combine signals and/or data, and in an opposite direction of communication separate signals and/or data. For signals and/or data routed from the memory chips 126 to a host, for instance, at least one buffer(s) 206 may separate the signals and/or data for further transmission to the host. For signals and/or data routed in the opposite direction, e.g., from the host to the memory chips 126, though, the at least one buffer(s) 206 may combine the signals and/or data into one or more channels for further routing to the memory chips 126.

In one or more implementations, the memory system 124 is configured to support a multi-channel architecture, where the memory chips 126 are accessed over multiple channels of the architecture, e.g., over two or more channels. For example, a first group or cluster of the memory chips 126 is accessed over a first channel (e.g., Channel A), and a second group or cluster of the memory chips 126 is accessed over a second channel (e.g., Channel B). It is to be appreciated that the memory system 124 may support access over more than two channels, e.g., a third channel (e.g., Channel C), a fourth channel (e.g., Channel D), and so on. Broadly, a “channel” is a physical pathway or bus that facilitates communication between a memory controller and the memory die 202, and in various implementations enables parallel data transfer through the use of multiple channels.

While in some implementations an individual memory chip 126 is accessed over just one channel of the multiple channels (e.g., all the memory die 202 of the individual memory chip are accessed over the one channel), in variations, an individual memory chip 126 may be accessed over at least two of the multiple memory channels (e.g., a portion of the memory die 202 of the individual chip is accessed over a first channel and a different portion of the memory die 202 of the individual chip is accessed over a second channel). In at least one variation, the memory system 124 supports a combination of such access, such that a first set of the memory chips 126 (at least one memory chip) is accessed entirely by a first channel, a second set of the memory chips 126 (at least one memory chip) is accessed entirely by a second channel, and a third set of the memory chips 126 (at least one memory chip) is accessed by both the first channel and the second channel (i.e., split access). In one or more implementations, such split access may be handled by a buffer 206 that is configured to facilitate access to the appropriate memory die of the memory chips 126 with the split access, such as for memory reads and/or memory writes. One or more of the memory chips 126 may be configured for such split access in scenarios where the memory system 124 is configured for error correcting code (ECC) use, for example. It is to be appreciated that access via multiple channels to the memory chips 126 may be arranged in a variety of ways for different numbers of channels, and include, for instance, one or more memory chips 126 that are accessed entirely over just one of the multiple channels and one or more memory chips 126 that are accessed over at least two of the channels (e.g., over at least a first channel and a second channel), without departing from the described techniques.

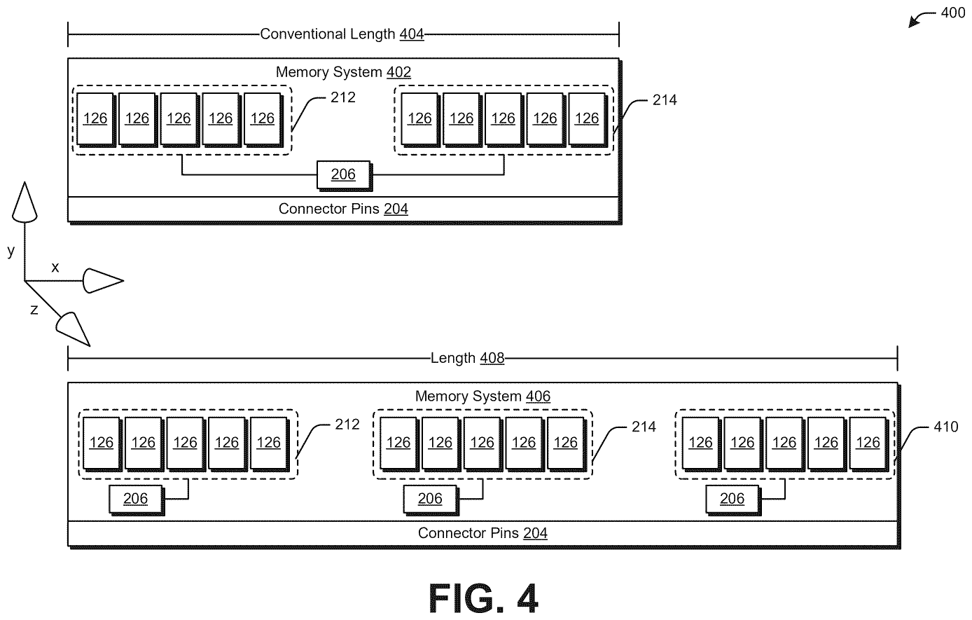

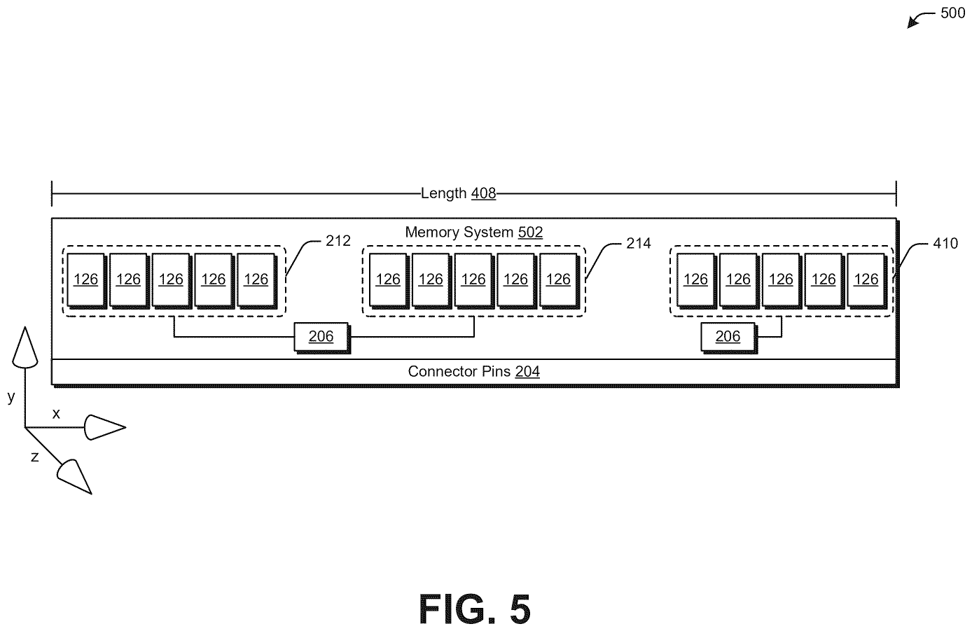

The illustrated example is depicted with an indication of a first cluster 212 of the memory chips 126 and an indication of a second cluster 214 of the memory chips 126. In at least one implementation, the first cluster 212 of the memory chips 126 is accessed over a first channel (and via respective buffer(s) 206 and connector pins 204), and the second cluster 214 of the memory chips 126 is accessed over a second channel (and via respective buffer(s) 206 and connector pins 204). For instance, read and write accesses of the first cluster 212 of memory chips 126 are serviced over the first channel, while read and write accesses of the second cluster 214 of memory chips 126 are serviced over the second channel. Although not shown in this figure, with the extended length, the memory system 124 can be configured to support a third cluster of the memory chips 126 that is accessed over a third channel, and via one of the buffers 206 and connector pins 204. Such configurations are depicted in more detail in FIG. 4 and FIG. 5.

In at least one variation, while the memory chips 126 are clustered into multiple clusters, the clustering may not correspond to channels over which the memory chips 126 are accessed. Instead, for instance, despite being physically clustered on a printed circuit board, each of the memory chips 126 may be accessed over multiple channels (e.g., two channels), where one or more of the memory die 202 of individual chip are accessed over a first channel, and one or more other memory die 202 of the induvial chip are accessed over at least one other channel.

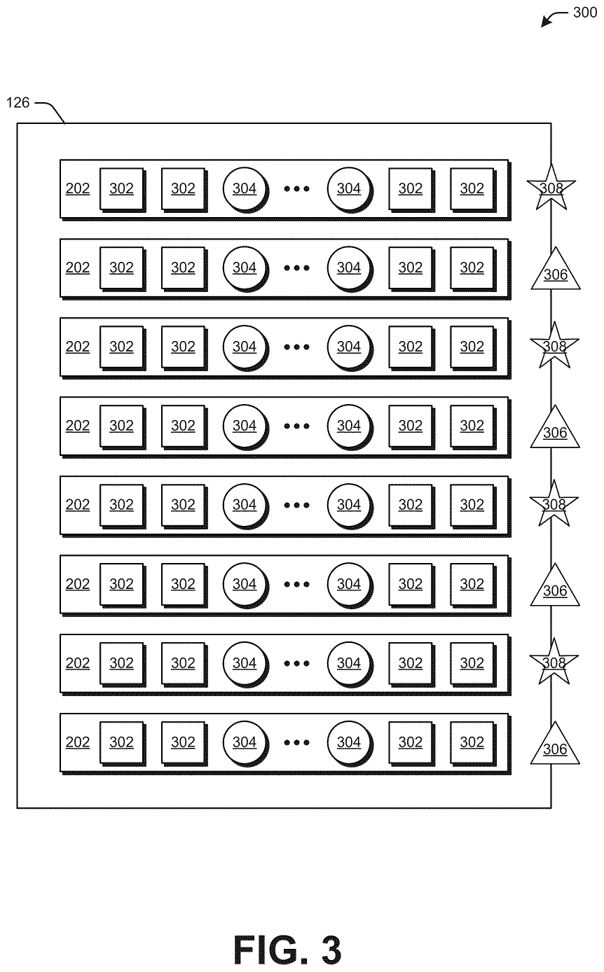

FIG. 3 is a block diagram of a non-limiting example 300 of pins of multiple memory die of a memory chip, such as of a stacked DRAM.

This figure depicts an example of one of the memory chips 126 having multiple memory die 202, such as when configured as a stacked DRAM. Here, each of the memory die 202 is shown with multiple pins 302, 304. As an example, the pins 302 correspond to data pins (DQ pins) and the pins 304 correspond to command/address pins (CA pins) of the memory die 202. In variations, the memory die 202 may have different numbers of pins, e.g., more pins or fewer pins. Additionally or alternatively, the memory die 202 may include different and/or additional types of pins (or pins configured for different functionality), examples of which include data strobe (DQS) pins, data mask (DM) pins, clock (CK) pins, chip select (CS) pins, and/or any other pin types used with DRAM.

The pins 302, 304 may be connected in a variety of ways to enable data to be read from and written to the memory die 202. In one or more implementations, the memory die 202 belong to ranks, e.g., rank zero (R0) or rank one (R1). Broadly, the ranks define a set of DRAM memory die that are connected to a same chip select and can therefore be accessed simultaneously. The illustrated example includes a first indication 306 and a second indication 308, which may represent a first rank (rank zero—R0) and a second rank (rank one—R1), respectively. In the illustrated example, the inclusion of these ranks indicates one possible division of the memory die 202 between the different ranks. In variations, the memory die 202 may be divided differently among ranks. Alternatively or additionally, there may be a different number of ranks than two, such as one rank, three ranks, and so on.

FIG. 4 is a block diagram of a non-limiting example 400 of a first memory module having a conventional length and a second memory module having a length that is greater than the conventional length.

The illustrated example depicts a memory system 402 having a conventional length 404 and also depicts a memory system 406 having a length 408 that is greater than the conventional length - an “extended” length. Broadly, memory systems, such as memory modules (e.g., DIMMs), may be configured according to a standard, e.g., a JEDEC DDR standard, which specifies a length of memory modules which comply with the standard. With DDR5, for example, compliant memory modules have a length of approximately 133.35 millimeters (or five and one-quarter (5¼) inches). Other conventionally configured memory modules may have lengths that are similar to but not the same as memory modules which comply with such a standard. For instance, some conventionally configured memory modules may have a length of 135 millimeters. Thus, conventional lengths of memory modules (e.g., DDR5 memory modules) may range between approximately 133.35 millimeters and 135 millimeters. As noted above, the term “approximately” or “approximate” when used in connection with a range of a conventional length of memory modules, can correspond to a range between 130 millimeters and 140 millimeters (inclusive). In the context of the illustrated example, the memory system 402 may, at least in terms of length, comply with the DDR5 (and DDR4) standard, such that the memory system 402's length, i.e., the conventional length 404, is approximately 133.35 millimeters (or five and one-quarter (5¼) inches.

By contrast, the memory system 406 has a length 408 that is greater than the conventional length 404 of the memory system 402, the length is “extended” relative to the conventional length. Because the length 408 is greater than the conventional length 404, the memory system 406 is longer than the memory system 402. In at least one implementation, the length 408 is approximately one and a half times greater than (i.e., 1.5×) the conventional length 404. Thus, in one or more implementations, the length 408 of the memory system 406 ranges between approximately 200.025 millimeters (seven and seven-eighths inches (7⅞ inches or 7.875 inches)) and 202.5 millimeters (7.97 inches). As noted above, the term “approximately” or “approximate” when used in connection with a range of the length of memory modules having the described novel configuration, can correspond to a range between 195.0 millimeters and 210.0 millimeters.

Typically, memory modules having a conventional length 404 may be configured with a first cluster 212 and a second cluster 214 of memory chips 126, which may support a first and a second channel. With the length 408, the memory system 406 may be able to support one and a half times (i.e., 1.5×) the number of memory chips 126 as the memory system 402 having the standard length, so three clusters of memory chips 126 rather than just two. Thus, in various implementations, the memory system 406 is long enough to include not only a first cluster 212 and a second cluster 214 of the memory chips 126, but also a third cluster 410 of the memory chips 126. Additionally, the memory system 406 may support three memory channels rather than the two channels supported by the memory system 402. Additionally, due to the length 408 of the memory system 406, the memory system 406 includes a greater number of connector pins 204 than memory systems having a conventional length. By way of example, memory systems having a conventional length may include two-hundred and eighty-eight (288) connector pins 204 (e.g., for DDR4 and DDR5). Thus, in one example, a conventional “pin count” is two-hundred and eighty-eight (288) connector pins. Other conventional pin counts include, for example, 168 connector pins (e.g., SDRAM), 184 connector pins (DDR1), and 240 connector pins (DDR2 and DDR3). In contrast, the length 408 of the memory system 406 enables the memory system 406 to have a pin count that is greater than a conventional pin count. In one or more implementations, for instance, the pin count of the memory system 406 may be approximately one and a half times (i.e., 1.5×) the conventional pin count, so four-hundred and thirty-two (432) connector pins.

The use of three channels does give rise to some additional difficulties, however. Whereas the memory system 402 with the conventional length 404 can support two channels for accessing the memory chips 126 with just a single buffer 206, in one or more implementations, the memory system 406 is equipped with more buffers 206 for handling more channels, e.g., three (3) channels. In one or more implementations, for instance, the memory system 406 is equipped with three buffers 206 for handling memory operations across three channels, e.g., one buffer per channel. Of course, the memory system 406 may be equipped with additional buffers 206 for purposes other than handling operation of the three channels. In one or more implementations, one or more of the buffer(s) 206 utilized in connection with the channels may include serial presence detect (SPD) hardware. Additionally, the buffer(s) 206 for handling the three channels may be integrated onto the memory system 406 in any of a variety of places, such as on a printed circuit board (front or back), within one or more of the memory chips 126, within one or more of the other components of the memory system 406, and so on. The greater (e.g., “extended”) length of the printed circuit board allows for increased memory capacity and bandwidth within a single module form factor while maintaining compatibility with existing memory architectures.

In one or more implementations, the memory system 406 includes one or more of serial presence detect (SPD) hardware or a hub to handle one versus two versus three or more subchannels. Additionally or alternatively, the memory system 406 includes one or more power management integrated circuits 208 to handle the higher power needs of the larger memory module.

In some implementations, the memory system 406 includes multiple voltage regulators distributed across the extended length of the printed circuit board. By way of example, these voltage regulators are configured to provide stable power supply to various components of the memory system, including the memory chips 126 and buffers 206. The greater length of the memory system 406 can introduce challenges in maintaining consistent voltage levels across the entire module. To address this, in variations, multiple voltage regulators are strategically placed at different locations along the printed circuit board. This contrasts with using just a single voltage regulator for the memory system. For example, a voltage regulator may be positioned near each cluster of memory chips (212, 214, 410) to ensure that each cluster receives an adequate and stable power supply.

In one or more implementations, the voltage regulators are designed to output a substantially fixed voltage, which helps maintain consistent performance across all components of the memory system 406. In at least one implementation, the voltage regulators are programmable or adjustable, allowing for fine-tuning of voltage levels to optimize performance or power efficiency.

The use of multiple distributed voltage regulators can also help in reducing power loss due to voltage drops over the greater (e.g., “extended”) length of the printed circuit board. This arrangement may contribute to improved overall system efficiency and thermal management of the memory system 406. Although using multiple voltage regulators is discussed, in at least one variation, a memory system having the greater length includes only a single voltage regulator.

In some implementations, the voltage regulators may be integrated with other components, such as the buffers 206 or power management integrated circuits 208, to optimize space utilization on the printed circuit board. Alternatively, such voltage regulators may be implemented as separate components, allowing for easier replacement or upgrades. The voltage regulators may also include features such as over-voltage protection, under-voltage protection, and current limiting to safeguard the memory chips 126 and other components from potential power-related issues. These protection mechanisms may help enhance the reliability and longevity of the memory system 406.

Although a buffer per channel is depicted in this example, in at least one variation, the memory system 406 may include a different number of buffers(s) 206 to handle the channels, such as only two buffer(s) 206 to handle the channels, where a first of the buffer(s) 206 is split to handle memory accesses over two channels and a second of the buffer(s) 206 handles just the memory accesses of a third channel. In this context consider, FIG. 5.

FIG. 5 is a block diagram of a non-limiting example 500 of a memory module having a length that is greater than the conventional length and having a different buffer configuration for handling memory channels than the preceding example.

The illustrated example depicts a memory system 502 having the length 408, e.g., ranging between approximately 200.025 millimeters and 202.5 millimeters. In contrast to the example depicted in FIG. 4, where the memory system 406 included three (3) individual buffer(s) 206 to handle each of the three (3) memory channels, the memory system 502 is depicted having just two (2) buffers to handle operations over the three channels. By way of example, a first of the buffers 206 is configured to handle memory accesses for a first and second channel, e.g., of the first cluster 212 of memory chips 126 and the second cluster 214 of memory chips 126. Further, a second of the buffers 206 is configured to handle memory accesses for a third channel, e.g., of the third cluster 410 of the memory chips. In variations, different numbers of buffers may be used to handle operations over any number of channels that an extended memory module is configured to support.

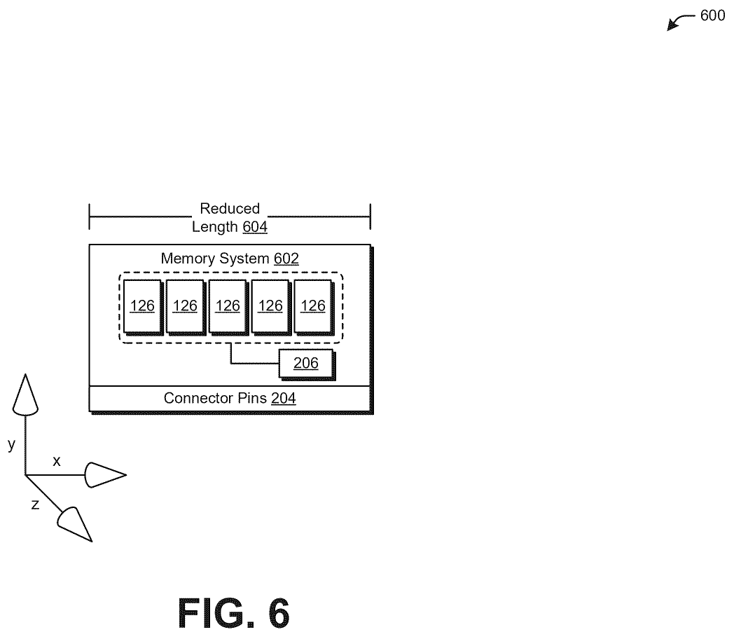

FIG. 6 is a block diagram of a non-limiting example 600 of a memory module having a length that is shorter than a conventional length.

The illustrated example depicts a memory system 602 having reduced length 604 relative to a conventional length 404. Because the reduced length 604 is less than the conventional length 404, the memory system 602 is shorter than the memory system 402. In at least one implementation, the reduced length 604 is approximately half of (i.e., 0.5×) the conventional length 404. In one or more implementations, the reduced length 604 of the memory system 602 ranges between approximately 66.675 millimeters and 67.5 millimeters. By way of example, the term “approximately” or “approximate” when used in connection with a range of the reduced length, can correspond to a range between 60.0 millimeters and 70.0 millimeters.

Due to the shortened length, the memory system 602 may only support operations with the memory chips 126 over a single memory channel and use a single buffer 206 to support those operations over the single channel.

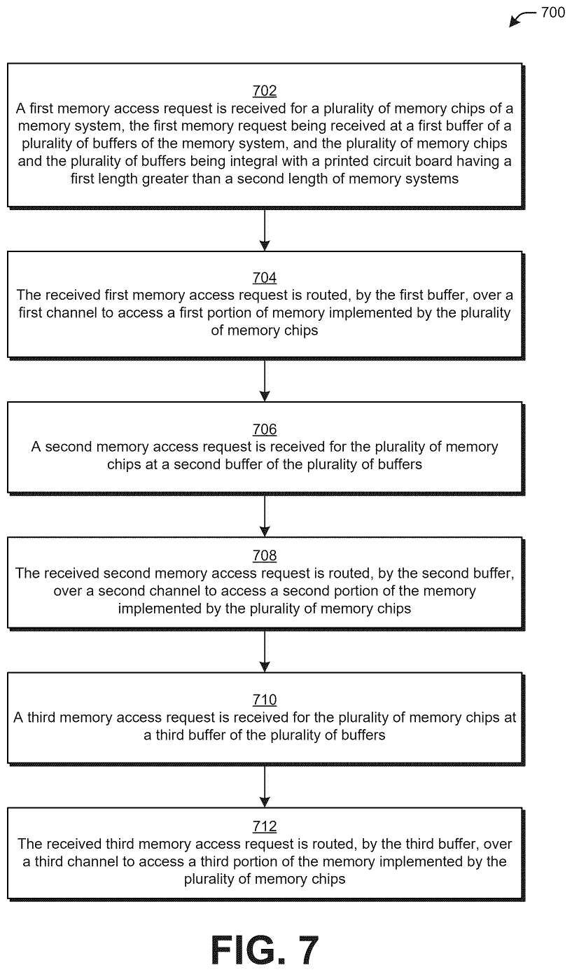

FIG. 7 depicts a procedure 700 in an example implementation of extended length memory system with multiple channels.

At a first buffer of a plurality of buffers of a memory system, a first memory access request is received for a plurality of memory chips of the memory system (block 702). In accordance with the principles discussed herein, the plurality of buffers and the plurality of memory chips are integrated within a printed circuit board of the memory system having a first length that is greater than a second length of memory systems. One example of the second length, is a length that complies with a standard of today such as memory systems configured according to JEDEC's DDR4 and DDR5 standards. By way of example, a first memory access request is received at a first buffer of the buffers 206 of the memory system 406. This first memory access request requests access to the plurality of memory chips 126 of the memory system 406. Examples of memory access requests include read requests, write requests, fetch requests, pre-fetch requests, and so on. The plurality of buffers 206 and the plurality of memory chips 126 are integrated with a printed circuit board of the memory system 406, and the printed circuit board of the memory system 406 has a length 408 greater than a length of some conventional memory systems (e.g., DIMMs which conform to DDR4 or DDR5).

Although the memory system 406 has the length 408 that is greater than a length, in one or more implementations, at least one of a height or thickness of the printed circuit board is approximately the same as conventional dimensions for memory systems. With DDR5, for example, compliant one-unit memory modules have a height of approximately 31.25 millimeters, within a range between 31.10 millimeters and 31.80 millimeters (inclusive), and compliant two-unit memory modules have a height of approximately 56.90 millimeters, within a range of 56.75 millimeters and 57.05 millimeters (inclusive). In at least one variation, although potentially non-compliant with the JEDEC standard in some constructions, the height of the memory system 406 may be between a range of 29.0 millimeters and 34.0 millimeters (inclusive). Alternatively, and also potentially non-compliant with the JEDEC standard in some constructions, the height of the memory system 406 may be between the range of 54.0 millimeters and 60.0 millimeters (inclusive). Another alternate range of the height is between 44.5 millimeters and 51.5 millimeters (inclusive). Regarding thickness, with DDR5, compliant memory modules of a first variation have a maximum thickness of approximately 5.57 millimeters, and compliant memory modules of a second variation have a maximum thickness of approximately of 3.37 millimeters.

The received first memory access request is routed, by the first buffer, over a first channel to access a first portion of memory implemented by the plurality of memory chips (block 704). By way of example, the memory access request received at block 702 is routed via the first buffer of the buffer(s) 206 over a first channel (e.g., physical connector) to access the first cluster 212 of the memory chips 126.

At a second buffer of the plurality of buffers, a second memory access request is received for the plurality of memory chips (block 706). In accordance with the principles discussed herein, the second buffer may be configured to handle memory operations for a different channel or set of memory chips than the first buffer. By way of example, a second memory access request is received at a second buffer of the buffers 206 of the memory system 406 and requests access to the plurality of memory chips 126 of the memory system 406.

The received second memory access request is routed, by the second buffer, over a second channel to access a second portion of the memory implemented by the plurality of memory chips (block 708). By way of example, the memory access request received at block 706 is routed via the second buffer of the buffer(s) 206 over a second channel (e.g., physical connector) to access the second cluster 214 of the memory chips 126.

At a third buffer of the plurality of buffers, a third memory access request is received for the plurality of memory chips (block 710). In some aspects, the third buffer may be configured to handle memory operations for a third channel or set of memory chips. By way of example, a third memory access request is received at a third buffer of the buffers 206 of the memory system 406, and this third memory access request requests access to the plurality of memory chips 126 of the memory system 406.

The received third memory access request is routed, by the third buffer, over a third channel to access a third portion of memory implemented by the plurality of memory chips (block 712). By way of example, the memory access request received at block 710 is routed via the third buffer of the buffer(s) 206 over a third channel (e.g., physical connector) to access the third cluster 410 of the memory chips 126. In some implementations, the third channel may provide access to memory chips located on a portion of the memory system 406 which corresponds to the greater length of the memory system 406 beyond the length of some conventional system. In one or more implementations, a memory system configured in accordance with the described techniques is configured to access memory implemented by the plurality of memory chips using only three channels.

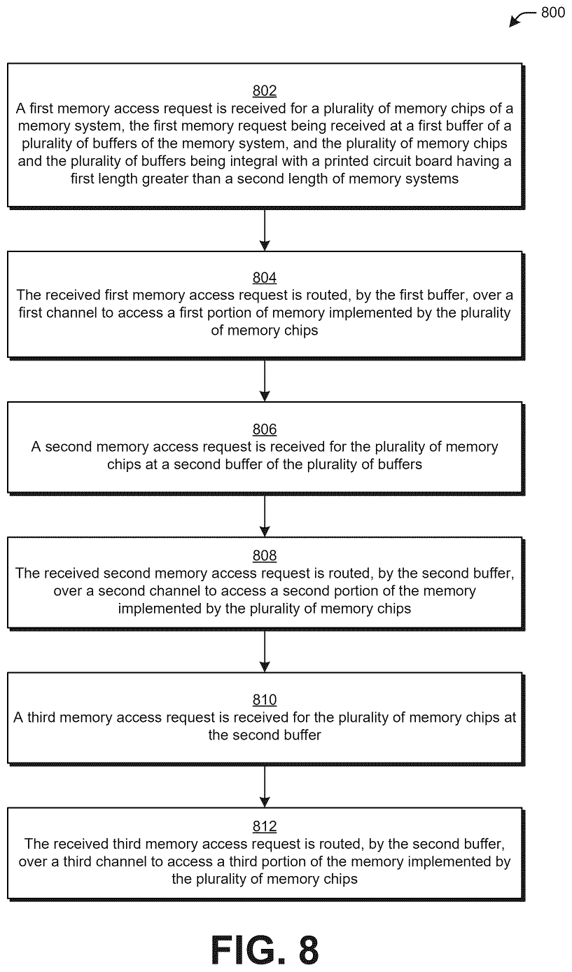

FIG. 8 depicts a procedure 800 in an example implementation of extended length memory system with multiple channels using a different buffer configuration from the preceding example.

In this example procedure 800, block 802 through block 808 are similar to the steps of block 702 through block 708 in the procedure 700 above. For instance, at a first buffer of a plurality of buffers of a memory system, a first memory access request is received for a plurality of memory chips of the memory system (block 802). In accordance with the principles discussed herein, the plurality of buffers and the plurality of memory chips are integrated within a printed circuit board of the memory system having a first length that is greater than a second length of memory systems. The received first memory access request is routed, by the first buffer, over a first channel to access a first portion of memory implemented by the plurality of memory chips (block 804). At a second buffer of the plurality of buffers, a second memory access request is received for the plurality of memory chips (block 806). In accordance with the principles discussed herein, the second buffer may be configured to handle memory operations for a different channel or set of memory chips than the first buffer. The received second memory access request is routed, by the second buffer, over a second channel to access a second portion of the memory implemented by the plurality of memory chips (block 808).

In contrast to the procedure 700, in the procedure 800, at the second buffer, a third memory access request is received for the plurality of memory chips (block 810). Notably in this example, the second buffer is configured to handle memory operations for multiple channels, such as for both the second and third channels. By way of example, a third memory access request is received at the second buffer of the buffers 206 of the memory system 406, and this third memory access request requests access to the plurality of memory chips 126 of the memory system 406.

Further, the received third memory access request is routed, by the second buffer, over a third channel to access a third portion of memory implemented by the plurality of memory chips (block 812). By way of example, the memory access request received at block 810 is routed via the second buffer of the buffer(s) 206 over a third channel (e.g., physical connector) to access the third cluster 410 of the memory chips 126. In some implementations, the third channel may provide access to memory chips located on the extended length portion of the memory system 406. In implementations, where only two buffers 206 are used to handle memory operations (e.g., memory access requests) of the memory system over three channels, one of those two buffers handles the memory operations over two of the three channels while a second of the buffers handles the memory operations over just one channel. In the context of FIG. 8, for instance, the second buffer handles memory operations over two such channels, receiving memory access requests for the two channels and routing each of those requests via the appropriate channel of the two channels to access a respective channel of the memory. In one or more implementations, a memory system configured in accordance with the described techniques is configured to access memory implemented by the plurality of memory chips using only three channels.

It is to be appreciated that the figures are not drawn to scale in the illustrated examples, and the various shapes used in the figures to represent various components may differ (perhaps significantly) from the actual shapes of those components in implementation.

What is claimed is:

1. A memory system, comprising:
a printed circuit board having a first length greater than a second length of memory systems;
a plurality of memory chips mounted on the printed circuit board; and
a plurality of buffers mounted on the printed circuit board, wherein the plurality of buffers are configured to handle memory access requests across at least three channels for accessing the plurality of memory chips.

2. The memory system of claim 1, wherein the second length is between a range of approximately 133.35 millimeters and 135 millimeters.

3. The memory system of claim 1, wherein the first length is between a range of approximately 200.025 millimeters and 202.5 millimeters.

4. The memory system of claim 1, wherein the plurality of buffers comprises three buffers each configured to handle the memory access requests for a respective one of the at least three channels.

5. The memory system of claim 1, wherein the plurality of buffers comprises a first buffer and a second buffer, wherein the first buffer is configured to handle the memory access requests for two of the at least three channels and the second buffer is configured to handle the memory access requests for a third channel.

6. The memory system of claim 1, wherein the plurality of memory chips comprises dynamic random-access memory (DRAM) chips, and wherein at least one of the DRAM chips is a stacked DRAM comprising multiple memory die.

7. The memory system of claim 1, further comprising a memory controller integral with the printed circuit board.

8. The memory system of claim 1, wherein the memory system has a first pin count of connector pins that is greater than a second pin count of memory systems.

9. The memory system of claim 1, further comprising a plurality of voltage regulators distributed across the first length of the printed circuit board to output a substantially fixed voltage to at least one of the plurality of memory chips or the plurality of buffers.

10. A method comprising:
receiving, at a first buffer of a plurality of buffers of a memory system, a first memory access request for a plurality of memory chips of the memory system, wherein the plurality of buffers and the plurality of memory chips are integral with a printed circuit board of the memory system having a first length greater than a second length of memory systems;
routing, by the first buffer, the received first memory access request over a first channel to access a first portion of memory implemented by the plurality of memory chips;
receiving, at a second buffer of the plurality of buffers, a second memory access request for the plurality of memory chips of the memory system;
routing, by the second buffer, the received second memory access request over a second channel to access a second portion of the memory implemented by the plurality of memory chips;
receiving, at a third buffer of the plurality of buffers, a third memory access request for the plurality of memory chips of the memory system; and
routing, by the third buffer, the received third memory access request over a third channel to access a third portion of the memory implemented by the plurality of memory chips.

11. The method of claim 10, wherein the memory system is configured to access the memory implemented by the plurality of memory chips using only three channels.

12. The method of claim 10, further comprising receiving the first memory access request via a first plurality of connector pins of the memory system, receiving the second memory access request via a second plurality of connector pins of the memory system, and receiving the third memory access request via a third plurality of connector pins of the memory system.

13. The method of claim 12, wherein the first plurality of connector pins, the second plurality of connector pins, and the third plurality of connector pins total a first pin count that is greater than a second pin count of memory systems.

14. The method of claim 10, wherein the first memory access request, the second memory access request, and the third memory access request are received from a host to which the memory system is connected via connector pins of the memory system.

15. The method of claim 14, wherein the host is a system on chip.

16. The method of claim 10, wherein at least one memory chip of the plurality of memory chips is a stacked dynamic random-access memory (DRAM) with multiple memory die.

17. A computing system, comprising:
a processor;
a memory controller communicatively coupled to the processor; and
a memory system communicatively coupled to the memory controller, the memory system comprising:
a printed circuit board having a first length greater than a second length of memory systems;
a plurality of memory chips mounted on the printed circuit board; and
a plurality of buffers mounted on the printed circuit board, wherein the plurality of buffers are configured to handle memory access requests across at least three channels for accessing the plurality of memory chips, and wherein the memory controller is configured to communicate with the memory system via the at least three channels.

18. The computing system of claim 17, wherein the processor is a central processing unit or an accelerated unit.

19. The computing system of claim 17, wherein the memory controller is included in the memory system.

20. The computing system of claim 17, wherein the processor is configured to execute instructions to perform operations on data accessed from the plurality of memory chips via the at least three channels.
